(19) United States
(12) Patent Application Publication
(10) Pub. No.: US 2026/0358450 A1
(43) Pub. Date: Nov. 12, 2026

(54) LOCKABLE ROTOR FOR LOW-TEMPERATURE NMR SPECTROSCOPY

(71) Applicant: COMMISSARIAT A L'ENERGIE ATOMIQUE ET AUX ENERGIES ALTERNATIVES, Paris (FR)

(72) Inventors: Eric BOULEAU, Grenoble Cedex 9 (FR); Gaël DE PAËPE, Grenoble Cedex 9 (FR); Florian BANCEL, Grenoble Cedex 9 (FR)

(73) Assignee: COMMISSARIAT A L'ENERGIE ATOMIQUE ET AUX ENERGIES ALTERNATIVES, Paris (FR)

(21) Appl. No.: 19/125,139

(22) PCT Filed: Nov. 2, 2023
(86) PCT No.: PCT/EP2023/080579

§ 371 Date: Apr. 28, 2025

(30) Foreign Application Priority Data
Nov. 8, 2022 (FR) FR2211623

(51) Int. Cl. G01R 33/30; G01R 33/46

(52) U.S. Cl. CPC G01R 33/307; G01R 33/46

(57) ABSTRACT

A lockable rotor for low-temperature NMR spectroscopy that includes a tubular body having at at least one of its longitudinal ends, or open end(s), a cavity which opens to the outside in order to contain a sample, and a blocking relief, a plug configured to fit into one of the open ends of the tubular body in order to seal it, the plug including a blocking relief so as to engage with the relief of the body in order to block the plug in the body, when fitting the plug into the body, and/or a cap configured to fit around one of the open ends of the tubular body in order to seal it, the cap having a coefficient of thermal contraction greater than or equal to the coefficient of thermal contraction of the tubular body.

### TECHNICAL FIELD

The present invention relates to the field of nuclear magnetic resonance (NMR) spectroscopy.

It relates more particularly to a rotor housing a sample to be analyzed by NMR.

### Prior Art

Nuclear magnetic resonance (NMR) spectroscopy is a non-destructive analysis method using the nuclear magnetic resonance (NMR) phenomenon, notably for figuring out molecular structures.

NMR occurs when atomic nuclei with non-zero spins are placed in a static magnetic field and when they are excited by electromagnetic radiation. This method is used particularly in organic chemistry, inorganic chemistry, biology and materials science.

In solid-state NMR spectroscopy, it is customary to place the sample to be analyzed in a rotor in order to cause it to rotate about an axis 44′ inclined by 54°, referred to as the magic angle, with respect to the static magnetic field.

The rotor, also called sample holder, usually comprises a tubular body housing within it the conditioned sample in the form of powder, and at least one plug for closing the tubular body. A carrier fluid levitates the rotor arranged in a stator. The rotor is generally driven in rotation pneumatically. In order to ensure the rotation, the rotor comprises blades at one of its longitudinal ends, forming a turbine which generally delimits the outer periphery of the plug. A driving fluid propelled onto the turbine thus rotates the rotor at frequencies ranging from a few kHz to several tens of Hz.

In order to ensure the physical integrity and the pneumatic rotation for this range of rotation frequencies, the tubular body of the rotor is usually produced from a ceramic, for example an alloy comprising zirconium and yttrium. The tubular body may also be made of sapphire. These materials have the advantage, owing to their low magnetic susceptibility, of not causing the NMR measurements to be affected by noise.

The material from which the turbine is produced has to withstand the mechanical stresses induced by the high rotation frequencies. This material also has to be sufficiently elastic such that the plug can be positioned on assembly in the tubular body while generating a clamping force that is sufficient to ensure that it is held in position. Specifically, any variation in speed at these high rotation frequencies creates a torque which tends to uncouple the plug from the tubular body. The material generally used for the plug and the turbine is Vespel®.

Furthermore, it is also known that the increase of the intensity of the magnetic field, the increase of the rotation frequency of the rotor, and/or the use of the dynamic nuclear polarization (DNP) phenomenon make it possible to improve the sensitivity and the resolution of the NMR spectroscopy.

It has been proven that, during an NMR analysis, the lower the temperature the greater the signal-to-noise ratio and the greater the gain due to the DNP phenomenon. Thus, high-resolution NMR spectrometers generally operate at low temperature, notably around 100 K. Article describes an NMR spectrometer which uses the DNP phenomenon and operates at temperatures less than 100 K.

To date, the materials constituting the tubular body and the plug have different thermal contraction coefficients. This results in a contraction differential between the tubular body and the plug during the lowering of the temperature, the plug contracting more than the tubular body. This contraction differential causes the clamping force of the plug in the tubular body to decrease down to virtually zero for temperatures of approximately 100 K. Consequently, at these temperatures, the slightest variation of the rotation frequency of the rotor results in a torque which tends to uncouple the plug from the tubular body. There is then no longer an effect for driving the entire rotor in rotation by the turbine and the plug no longer closes the tubular body, possibly leading to the loss of the sample.

To solve this problem, it would be possible to envisage increasing the clamping force at ambient temperature between the plug and the tubular body. This solution is not feasible because this would make it impossible to manually introduce the plug into the tubular body, and would make it more complex or even impossible to extract the plug after the NMR measurement without damaging the tubular body.

Patent U.S. Pat. No. 10,914,799 B2 describes a rotor for NMR spectroscopy, comprising a tubular body and a plug comprising a hub, the material of which has a negative thermal contraction coefficient. Thus, the hub expands when the temperature decreases, making it possible to maintain a sufficient clamping torque for clamping the plug in the tubular body in order to carry out low-temperature NMR spectroscopy. However, the manufacture of the plug in patent U.S. Pat. No. 10,914,799 B2 is particularly complex, notably because the plug is of very small size and therefore requires extremely precise machining and preparation.

There is therefore a need for a rotor which is adapted for low-temperature NMR spectroscopy and overcomes the aforementioned drawbacks. Notably, there is a need for a rotor which is adapted for low-temperature NMR spectroscopy, is simple to manufacture and the plug of which does not uncouple from the tubular body during a rotation of the rotor at low temperature.

The aim of the invention is to address, at least partially, this/these need/needs.

### SUMMARY OF THE INVENTION

To this end, the invention relates to a rotor for nuclear magnetic resonance (NMR) spectroscopy, extending along a longitudinal axis and comprising:
a tubular body comprising, at at least one of its longitudinal ends, referred to as open end(s), a cavity opening out toward the outside and intended to contain a sample to be analyzed by NMR, and, within said body, at least one blocking relief;
at least one plug configured to be at least partially fitted in one of the open ends of the tubular body so as to close it, the plug comprising a blocking relief of complementary shape to the relief of the tubular body such that, when the plug is fitted in the body, said blocking reliefs engage with one another and thus block the plug in the body; and/or
at least one cap configured to be at least partially fitted around one of the open ends of the tubular body of the body of the tubular so as to close it, the cap having a thermal contraction coefficient that is greater than or equal to the thermal contraction coefficient of
the tubular body so as to block the cap in the body, during operation of the rotor.

The thermal contraction coefficient of a component corresponds to its ability to contract during a decrease in the temperature. The higher the thermal contraction coefficient, the greater the contraction will be.

Preferably, the blocking relief of the tubular body is a radial groove provided internally in the thickness of the tubular body and the blocking relief of the plug is a radial rib which is at the outer periphery of the plug and is arranged to clip-fasten in the groove, when the plug is fitted in the body.

Alternatively, the blocking relief of the plug may be a groove provided in the thickness at the radial outer periphery of the plug and the blocking relief of the tubular body may be a radial inner rib arranged to clip-fasten in the groove, when the plug is fitted in the body.

Preferably, the groove and the rib each have an annular shape.

Preferably, the groove has a depth that is greater than or equal to 0.1 mm and/or the rib has a height that is greater than or equal to 0.1 mm.

Preferably, the plug comprises a cover and a sleeve configured to be fitted in the tubular body with the cover projecting, preferably in abutment, at the open end of the tubular body, the sleeve comprising, on its outer periphery, the blocking relief of the plug.

Preferably, the sleeve is split, preferably comprising at least two slots extending along the length of the sleeve.

Preferably, the sleeve has a length of between 1.2 and 1.8 mm.

Preferably, the sleeve has an outer diameter that is greater than the opening diameter of the open end, for example the outer diameter of the sleeve is between 2.4 and 2.7 mm.

Preferably, the difference between the outer diameter of the cover and the outer diameter of the body at its open end is less than or equal to 0.05 mm. Preferably, the outer diameter of the cover is substantially equal to the outer diameter of the body at its open end.

Preferably, the rotor comprises an insert configured to be housed in the sleeve so as to press the sleeve against the wall of the cavity and thus mechanically lock the plug blocked in the body.

Preferably, the cover comprises a threaded opening opening out in the sleeve and the insert is configured to be screwed in said opening.

Preferably, the insert is made of polymer, preferably of polyether ether ketone.

Preferably, the cap comprises a cover and a hollow sleeve configured to be fitted around the open end of the tubular body with the cover projecting.

Preferably, the sleeve is configured to be tightly fitted around the tubular body.

Preferably, the difference between the outer diameter of the cover and the outer diameter of the sleeve is less than or equal to 0.05 mm. Preferably, the outer diameter of the cover is substantially equal to the outer diameter of the sleeve.

Preferably, the tubular body portion around which the cap is intended to be fitted, referred to as fitting portion, has an outer diameter that is reduced with respect to the outer diameter of the rest of the tubular body.

Preferably, the difference between the outer diameter of the sleeve of the cap and the outer diameter of the tubular body beyond its fitting portion is less than or equal to 0.05 mm. Preferably, the outer diameter of the sleeve is substantially equal to the outer diameter of the tubular body beyond its fitting portion.

Preferably, the plug and/or the cap are made of plastics material, preferably of polyimide-based polymer, for example of Vespel®. Advantageously, a plug and/or a cap produced from these materials has a very low magnetic susceptibility, and this limits the noise during NMR spectroscopy. Furthermore, these materials are resistant to the mechanical stresses due to the high rotation frequencies during NMR spectroscopy. They are also flexible, facilitating the fitting of the plug and/or of the cap.

Preferably, the rotor comprises blades forming a turbine.

According to a first embodiment, the cavity may open out only at a single end of the tubular body, referred to as open end, the rotor comprising a plug or a cap according to the foregoing in order to close said open end.

The turbine may be comprised by the plug or by the cap. Preferably, the blades are formed in the cover of the plug or in the cover of the cap.

Alternatively, the rotor may comprise a cylindrical component in which the blades of the turbine are formed, the cylindrical component being configured to be fixed, preferably by interference fit, at the end of the tubular body opposite the open end. The cylindrical component may be made of plastic, preferably of polyimide-based plastic, for example of Vespel®.

According to a second embodiment, the cavity may open out at the two ends of the tubular body, referred to as open ends, the rotor comprising two plugs according to the foregoing in order to close each of the open ends, at least one of the plugs comprising a turbine. Preferably, the blades are formed in the cover of the plug(s) comprising a turbine. Preferably, the cover of a plug that does not comprise a turbine is relatively smooth.

According to a third embodiment, the cavity may open out at the two ends of the tubular body, referred to as open ends, the rotor comprising two caps according to the foregoing in order to close each of the open ends, at least one of the caps comprising a turbine. Preferably, the blades are formed in the cover of the cap(s) comprising a turbine. Preferably, the cover of a cap that does not comprise a turbine is relatively smooth.

According to a fourth embodiment, the cavity may open out at the two ends of the tubular body, referred to as open ends, the rotor comprising a plug and a cap according to the foregoing in order to close each of the open ends, the plug and/or the cap comprising a turbine. Preferably, the blades are formed in the cover of the plug and/or of the cap comprising a turbine. Preferably, the cover of the plug or cap that does not comprise a turbine is relatively smooth.

Preferably, the tubular body has a cylindrical shape with a length of between 10 and 20 mm and/or an outer diameter of between 0.7 and 4.0 mm.

Preferably, the open end(s) has (have) an opening diameter of between 0.5 and 3.6 mm.

Preferably, the tubular body is made of ceramic, preferably of zirconium-based ceramic, for example of a mixture of zirconium and yttrium. Advantageously, a body produced from these materials has a very low magnetic susceptibility, and this limits the noise during NMR spectroscopy. Furthermore, these materials are resistant to the mechanical stresses due to the high rotation frequencies during NMR spectroscopy.

Preferably, the weight of the rotor is less than or equal to 1 g.

The invention also relates to a spectroscope for nuclear magnetic resonance (NMR) spectroscopy, comprising a rotor according to the present invention.

The present invention therefore essentially consists in a rotor for nuclear magnetic resonance spectroscopy, comprising a plug and/or a cap for closing the cavity of the tubular body. The plug and/or the cap are adapted to be kept fitted in or around the tubular body even in the case 4 a strong decrease in temperature causing a contraction differential between the plug, and respectively the cap, and the tubular body. During NMR spectroscopy, the plug and/or the cap remain secured to the tubular body even in the case of a variation of the rotation frequency of the rotor resulting in a rotational torque that may be significant between the plug, and respectively the cap, and the tubular body.

Furthermore, the rotor according to the present invention is simple to manufacture and does not require precision machining that would prove to be expensive.

### BRIEF DESCRIPTION OF THE DRAWINGS

Further advantages and features will become better apparent from reading the detailed description given by way of non-limiting illustration with reference to the following figures:

FIG. 1 is a schematic view in longitudinal section of a rotor for NMR spectroscopy according to the present invention, the rotor comprising a plug and a tubular body with an opening at one end, the other end being closed;

FIG. 2 is a schematic view in longitudinal section of a rotor for NMR spectroscopy according to the present invention, the rotor comprising two plugs and a tubular body with an opening at each of its ends;

FIG. 3 is a schematic view in longitudinal section of a rotor for NMR spectroscopy according to the present invention, the rotor comprising a cap and a tubular body with an opening at one end, the other end being closed;

FIG. 4 is a schematic view in longitudinal section of a rotor for NMR spectroscopy according to the present invention, the rotor comprising two caps and a tubular body with an opening at each of its ends;

FIG. 5 is a schematic view in longitudinal section of a rotor for NMR spectroscopy according to the present invention, the rotor comprising a cap and a tubular body with an opening at one end, the other end being closed and having fixed thereto a cylindrical component forming a turbine.

### DETAILED DESCRIPTION

For reasons of clarity, the various elements in the figures are shown on a free scale, the actual dimensions of the various parts not necessarily being respected.

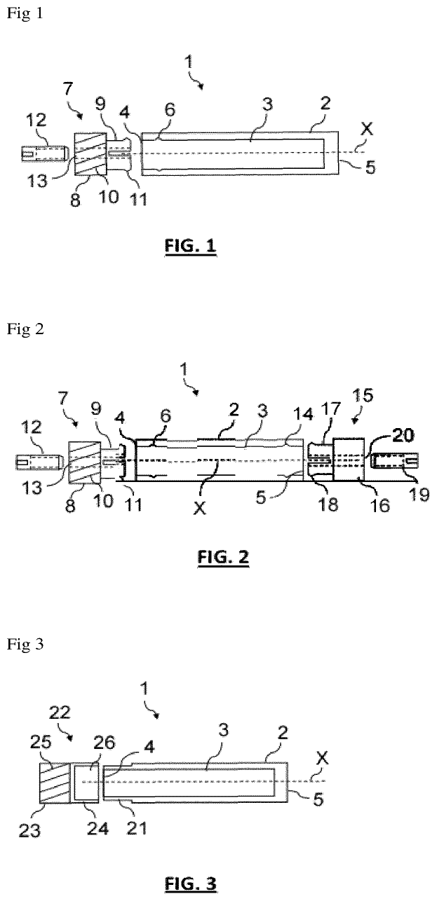

FIG. 1 illustrates one embodiment of a rotor 1 of longitudinal axis X for NMR spectroscopy according to the present invention. The rotor 1 comprises a blind body 2 of hollow tubular shape, the cavity 3 of which extends over part of the length of the body 2. The blind cavity 3 opens out at one of the longitudinal ends 4 of the body 2. The closed longitudinal end 5 of the body 2 may be flat-bottomed. The body 2 also comprises a blocking groove 6 provided in its thickness at the inner periphery of the cavity 3 and in the vicinity of the open end 4.

The rotor 1 also comprises a plug 7 comprising a cover 8 and a split sleeve 9 in the longitudinal continuation of the cover 8. The plug 7 is preferably in one piece. The cover 8 has an outer diameter that is greater than the inner diameter of the body 2 delimiting the cavity 3. The outer diameter of the cover 8 is notably greater than the outer diameter of the split sleeve 9, thus forming a shoulder. The cover 8 has blades 10 on its radial outer periphery, forming a turbine. The split sleeve 9 comprises, on its radial outer periphery, a blocking rib 11 in the form of a ring.

The split sleeve 9 is configured to be fitted in the cavity 3 of the body 2. The slot or slots of said sleeve 9 make the latter flexible, facilitating its insertion in the cavity 3.

During the fitting, the blocking rib 11 clip-fastens in the blocking groove 6, thus ensuring the mechanical blocking of the plug 7 in the body 2.

When the sleeve 9 is inserted and blocked in the cavity 3, the cover 8 is in abutment against the body 2.

The depth of the groove 6 and the height of the rib 11 are selected such that, in spite of the contraction differential between the plug 7 and the body 2 during a decrease in the temperature, for example from a temperature of 293 K down to a temperature of less than or equal to 100 K, for example down to a temperature of between 10 K and 80 K, the rib 11 remains clip-fastened in the groove 6.

Furthermore, the cover 8 comprises a longitudinal through-opening 13 which is threaded over at least part of its length and that of the split sleeve 9.

Once the split sleeve 9 has been fitted in the body 2, a threaded insert 12 can be screwed in the threaded opening 13 until it is inserted in the split sleeve 9.

This insert 12 thus screwed ensures mechanical locking of the split sleeve 9 blocked in the cavity 3.

In the embodiment illustrated in FIG. 1, the rotor 1 has a length equal to 17 mm, a diameter equal to 3.2 mm and a total mass equal to 0.1 g.

FIG. 2 illustrates another embodiment of a rotor 1 for NMR spectroscopy according to the present invention. The rotor 1 is similar to the one illustrated in FIG. 1, except for the fact that the cavity 3 of the body 2 is a through-cavity, and therefore that the other end 5 of the body 2 is open. The body 2 comprises a second blocking periphery of the cavity 3 and in the vicinity of the other open end 5.

The rotor 1 also comprises a second plug 15 comprising a cover 16 and a split sleeve 17 in the longitudinal continuation of the cover 16. The cover 16 has an outer diameter that is greater than the opening diameter of the cavity 3 at the open end 5. The outer diameter of the cover 16 is notably greater than the outer diameter of the split sleeve 17, thus forming a shoulder. The cover 16 has a relatively smooth outer surface. The split sleeve 17 comprises, on its radially outer periphery, a blocking rib 18 in the form of a ring.

The split sleeve 17 is configured to be fitted in the cavity 3 of the body 2. The slot or slots of said sleeve 17 make the latter flexible, facilitating its insertion in the cavity 3. During the fitting, the rib 18 clip-fastens in the second groove 14, thus ensuring the mechanical blocking of the second plug 15 in the body 2. When the sleeve 17 is inserted in the cavity 3, the cover 16 is in abutment against the open end 5 of the body 2.

The depth of the second groove 14 and the height of the rib 18 are selected such that, in spite of the contraction differential between the second plug 15 and the body 2 during a decrease in the temperature, for example from a temperature of 293 K down to a temperature of less than or equal to 100 K, the rib 18 remains clip-fastened in the second groove 14.

Furthermore, the cover 16 comprises a longitudinal through-opening 20 which is threaded over at least part of its length and that of the split sleeve 17.

Once the split sleeve 17 has been fitted in the body 2, a threaded insert 19 can be screwed in the threaded opening 13 until it is inserted in the split sleeve 17.

This insert 19 thus screwed ensures mechanical locking of the split sleeve 17 blocked in the cavity 3.

FIG. 3 illustrates another embodiment of a rotor 1 of longitudinal axis X for NMR spectroscopy according to the present invention. The rotor 1 comprises a blind body 2 of hollow tubular shape, the cavity 3 of which extends over part of the length of the body 2. The blind cavity 3 opens out at one of the longitudinal ends 4 of the body 2. The closed longitudinal end 5 of the body 2 may be flat-bottomed. The body 2 also comprises, at its open longitudinal end 4, a fitting portion 21 having an outer diameter that is reduced with respect to the outer diameter of the rest of the body 2, forming a shoulder.

The rotor 1 also comprises a cap 22 comprising a cover 23 and a sleeve 24 in the longitudinal continuation of the cover 13. The cover 23 comprises blades 25 on its radial outer periphery, forming a turbine.

The sleeve 24 has an opening 26 adapted to be fitted around the fitting portion 21 and thus close the cavity 3 in order to ensure the retention of a sample housed in the body 2. The fitting is carried out manually or automatically at a first temperature, for example at ambient temperature.

The sleeve 24 is produced from a material having a thermal contraction coefficient that is greater than the thermal contraction coefficient of the material constituting the fitting portion 21. Thus, during a temperature decrease, for example to a second temperature of less than or equal to 100 K, the contraction differential between the sleeve 24 and the fitting portion 21 creates a blocking force by clamping of the cap 22 around the body 2. This clamping force ensures the mechanical retention between the cap 22 and the body 2 during low-temperature NMR spectroscopy.

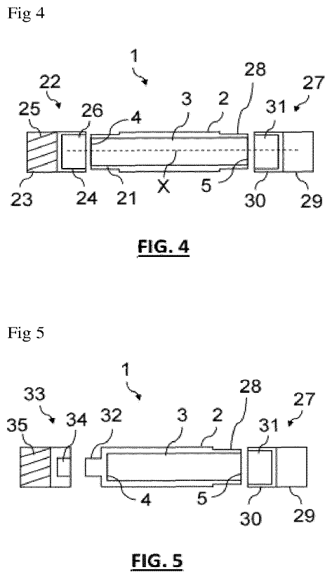

FIG. 4 illustrates another embodiment of a rotor 1 for NMR spectroscopy according to the present invention. The rotor 1 is similar to the one illustrated in FIG. 3, except for the fact that the cavity 3 of the body 2 is a through-cavity and that the rotor 1 comprises a second cap 27. Thus, the end 5 is open in this case. The body 2 comprises, at this open end 5, a second fitting portion 28 having an outer diameter that is reduced with respect to the outer diameter of the rest of the body 2, forming a shoulder.

The second cap 27 comprises a cover 29 and a sleeve 30 in the longitudinal continuation of the cover 29. The cover 29 has a relatively smooth outer surface. The sleeve 30 comprises an opening 31 adapted to be fitted around the fitting portion 28 and thus close the open end 5. The fitting is carried out manually or automatically at a first temperature, for example at 293 K.

The sleeve 30 is produced from a material having a thermal contraction coefficient that is greater than the thermal contraction coefficient of the material constituting the fitting portion 28. Thus, during a temperature decrease, for example to a second temperature of less than or equal to 100 K, the contraction differential between the sleeve 30 and the fitting portion 28 creates a blocking force by clamping of the second cap 27 around the body 2. This clamping force ensures the retention of the second cap 27 with the body 2 during low-temperature NMR spectroscopy.

FIG. 5 illustrates another embodiment of a rotor 1 for NMR spectroscopy according to the present invention. The rotor 1 comprises a hollow body 2 of tubular shape, the cavity 3 of which is blind. The body 2 comprises a fitting portion 28 at its open end 5. A plug 27 is provided so as to be fitted around said fitting portion 28 and thereby close the open end 5.

The body 2 comprises, at its closed end 4, a projecting portion forming a tenon 32. The rotor 1 also comprises a cylindrical component 33 comprising a mortise 34 and blades 35 on its outer radial surface, forming a turbine. The mortise 34 can be fixed by interference fit around the tenon 32, and thus block the cylindrical component 33 on the body 2. The interference fit can be effected at ambient temperature, that is to say approximately 293 K. During a temperature decrease, for example to a temperature of less than or equal to 100 K, the tenon 32 remains blocked in the mortise 34, ensuring the fixing of the cylindrical component 33 to the body 2.

In the embodiment in FIG. 5, the packing (housing) of a sample in the cavity 3 is effected via the open end 5. Thus, it is the cap 27 which ensures that the cavity 3 is closed during NMR spectroscopy. Advantageously, this cap 27 has a cover 29 with a relatively smooth surface which allows it to be subjected to a lesser extent to the driving fluid of the spectroscope, and therefore to be less sensitive to the rotational speed variations of the rotor 1.

Other variants and improvements may be envisaged without thereby departing from the scope of the invention.

### LIST OF THE CITED REFERENCES

[1]: Yoh Matsuki and Toshimichi Fujiwara, “Cryogenic Platforms and Optimized DNP sensitivity”, eMagRes, 2018,vol. 7:9-24.

1. A rotor for nuclear magnetic resonance (NMR) spectroscopy, extending along a longitudinal axis and comprising:
a tubular body comprising, at at least one of its longitudinal ends, referred to as open end(s), a cavity opening out toward the outside and intended to contain a sample to be analyzed by NMR, and, within said body, at least one blocking relief;
at least one plug configured to be at least partially fitted in one of the open ends of the tubular body so as to close it, the plug comprising a blocking relief of complementary shape to the relief of the tubular body such that, when the plug is fitted in the body, said blocking reliefs engage with one another and thus block the plug in the body, the blocking relief of the tubular body being a radial groove provided internally in the thickness of the tubular body and the blocking relief of the plug being a radial rib which is at the outer periphery of the plug and is arranged to clip-fasten in the groove, when the plug is fitted in the body, the depth of the groove and the height of the rib being selected such that, in spite of the contraction differential between the plug and the body during a decrease in temperature ranging from 293 K down to at most 100 K, the rib remains clip-fastened in the groove; and/or
at least one cap configured to be at least partially fitted around one of the open ends of the tubular body so as to close it, the cap having a thermal contraction coefficient that is greater than or equal to the thermal contraction coefficient of the tubular body so as to block the cap around the body, during operation of the rotor, the cap comprising a cover and a hollow sleeve configured to be fitted around the open end of the tubular body with the cover projecting, the tubular body portion around which the cap is intended to be fitted, referred to as fitting portion, having an outer diameter that is reduced with respect to the outer diameter of the rest of the tubular body, the difference between the outer diameter of the sleeve of the cap and the outer diameter of the tubular body beyond its fitting portion being less than or equal to 0.05 mm.

2. (canceled)

3. The rotor as claimed in claim 1, the plug comprising a cover and a sleeve configured to be fitted in the tubular body with the cover projecting, preferably in abutment, at the open end of the tubular body, the sleeve comprising, on its outer periphery, the blocking relief of the plug.

4. The rotor as claimed in claim 3, comprising an insert configured to be housed in the sleeve so as to press the sleeve against the wall of the cavity and thus mechanically lock the plug blocked in the body.

5. The rotor as claimed in claim 1, the plug and/or the cap being made of plastics material.

6. The rotor as claimed in claim 1, comprising blades forming a turbine.

7. The rotor as claimed in claim 1, the tubular body having a cylindrical shape with a length of between 10 and 20 mm and/or an outer diameter of between 0.7 and 4.0 mm.

8. The rotor as claimed in claim 1, the open end(s) having an opening diameter of between 0.5 and 3.6 mm.

9. The rotor as claimed in claim 1, the tubular body being made of ceramic.

10. The rotor as claimed in claim 1, the weight of the rotor being less than or equal to 1 g.

11. A spectroscope for nuclear magnetic resonance (NMR) spectroscopy, comprising a rotor as claimed in claim 1.

12. A rotor for nuclear magnetic resonance (NMR) spectroscopy, extending along a longitudinal axis and comprising:
a tubular body comprising, at at least one of its longitudinal ends, referred to as open end(s), a cavity opening out toward the outside and intended to contain a sample to be analyzed by NMR, and, within said body, at least one blocking relief;
at least one plug configured to be at least partially fitted in one of the open ends of the tubular body so as to close it, the plug comprising a blocking relief of complementary shape to the relief of the tubular body such that, when the plug is fitted in the body, said blocking reliefs engage with one another and thus block the plug in the body, the blocking relief of the plug being a groove provided in the thickness at the radial outer periphery of the plug and the blocking relief of the tubular body being a radial inner rib arranged to clip-fasten in the groove, when the plug is fitted in the body, the depth of the groove and the height of the rib being selected such that, in spite of the contraction differential between the plug and the body during a decrease in temperature ranging from 293 K down to at most 100 K, the rib remains clip-fastened in the groove; and/or
at least one cap configured to be at least partially fitted around one of the open ends of the tubular body so as to close it, the cap having a thermal contraction coefficient that is greater than or equal to the thermal contraction coefficient of the tubular body so as to block the cap around the body, during operation of the rotor, the cap comprising a cover and a hollow sleeve configured to be fitted around the open end of the tubular body with the cover projecting, the tubular body portion around which the cap is intended to be fitted, referred to as fitting portion, having an outer diameter that is reduced with respect to the outer diameter of the rest of the tubular body, the difference between the outer diameter of the sleeve of the cap and the outer diameter of the tubular body beyond its fitting portion being less than or equal to 0.05 mm.

13. The rotor as claimed in claim 12, the plug comprising a cover and a sleeve configured to be fitted in the tubular body with the cover projecting at the open end of the tubular body, the sleeve comprising, on its outer periphery, the blocking relief of the plug.

14. The rotor as claimed in claim 13, comprising an insert configured to be housed in the sleeve so as to press the sleeve against the wall of the cavity and thus mechanically lock the plug blocked in the body.

15. The rotor as claimed in claim 12, the plug and/or the cap being made of plastics material.

16. The rotor as claimed in claim 12, comprising blades forming a turbine.

17. The rotor as claimed in claim 12, the tubular body having a cylindrical shape with a length of between 10 and 20 mm and/or an outer diameter of between 0.7 and 4.0 mm.

18. The rotor as claimed in claim 12, the open end(s) having an opening diameter of between 0.5 and 3.6 mm.

19. The rotor as claimed in claim 12, the tubular body being made of ceramic.

20. The rotor as claimed in claim 12, the weight of the rotor being less than or equal to 1 g.

21. A spectroscope for nuclear magnetic resonance (NMR) spectroscopy, comprising a rotor as claimed in claim 12.
